(19) United States
(12) Patent Application Publication
(10) Pub. No.: US 2019/0364698 A1
(43) Pub. Date: Nov. 28, 2019

(54) Modular Containerized Data Center Cooling System With Hybrid Passive Geothermal-Vortex Exhaust Engine

(71) Applicant: Gunnisystems Inc., Golden, CO (US)

(72) Inventors: Matthew W. Johnson, Golden, CO (US); Jonathan C. Potter, Castle Rock, CO (US)

(21) Appl. No.: 16/416,874

(22) Filed: May 20, 2019

Related U.S. Application Data
(60) Provisional application No. 62/676,585, filed on May 25, 2018.

(51) Int. Cl. H05K 7/20; H05K 7/14; E04H 5/02

(52) U.S. Cl. CPC H05K 7/20745; E04H 2005/005; E04H 5/02; H05K 7/1497

(57) ABSTRACT

An example system for cooling a data center includes a container enclosure for housing server racks. An air intake collects ambient air. The system includes a cooling ladder base, a cooling ladder wing, and a mixing chamber. A first conduit connects the air intake with the cooling ladder wing. A second conduit connects the cooling ladder wing with the cooling ladder base. An intake tunnel connects the cooling ladder base to the mixing chamber. Underground cooling ladders carry the ambient air downward into the earth through cooling ladder rungs in the cooling ladder wing such that the ambient air becomes geothermally cooled air. The geothermally cooled air is provided through the at least one intake tunnel to the mixing chamber for release into the container enclosure for the data center. A chimney vents hot air exhaust outside of the data center.

### PRIORITY CLAIM

This application claims the priority benefit of U.S. Provisional Patent Application No. 62/676,585 filed May 25, 2018 titled “Modular Containerized Data Center Unit With Hybrid Passive Geothermal-Vortex Exhaust Engine” of Johnson and Potter, hereby incorporated by reference for all that is disclosed as though fully set forth herein.

### BACKGROUND

Data centers are large groups of computers used for high-performance computing, decentralized computing, streaming video, search engines, blockchain hashing calculations or mining calculations, and other power-intensive computation workloads. Because they generate heat proportional to their computation load, data centers require substantial cooling capacity.

Cooling may be supplied to the data center through a cold aisle chilled via high-volume, high-throughput mechanical air conditioning, which requires reliable access to very high-wattage electricity. Heat management may also be supplied through hydronic cooling, using water or another working fluid. This requires coolant tanks, cooling towers, heat exchangers, and extensive plumbing that may require frequent maintenance. These components are necessarily above ground, and provide a relatively low power-per-rack ratio and high cooling energy costs.

### BRIEF DESCRIPTION OF THE DRAWINGS

FIG. 1A is an exploded view of an example modular containerized data center cooling system.

FIG. 1B is a perspective view of the example modular containerized data center cooling system of FIG. 1A.

FIG. 1C is a perspective view of the example modular containerized data center cooling system.

FIG. 2A is an example floor panel for the modular containerized data center cooling system, specially configured to permit the passage of air through a subfloor into the main server chamber.

FIG. 2B is an example of diverter plates which may be installed inside of the server rack of the modular containerized data center cooling system.

FIG. 2C is an example server box for a server rack of the modular containerized data center cooling system

FIG. 3A is an exploded view of the modular containerized data center cooling system with a raised floor support and server rack star structures and exhaust chimneys.

FIG. 3B is an exploded view of the modular containerized data center cooling system illustrating an example airflow pattern.

FIG. 4 is a diagram illustrating an example airflow pattern through a server rack of the modular containerized data center cooling system.

FIG. 5 is a perspective view of an example cooling ladder of the example modular containerized data center cooling system.

FIG. 6 is a front perspective view of another cooling ladder of the example modular containerized data center cooling system.

FIG. 7 is a side perspective view of the cooling ladder shown in FIG. 6.

FIG. 8 is a perspective view of another modular containerized data center cooling system.

FIG. 9 is a perspective view of another modular containerized data center cooling system.

### DETAILED DESCRIPTION

A modular containerized data center cooling system with hybrid passive geothermal-vortex exhaust engine is disclosed. An example modular containerized data center cooling system includes a geothermal air cooling subsystem or “geothermal cooling ladder” including interconnected cast or precast concrete (or other suitable manufacture) moldings and pipes.

An example system for cooling a data center includes a container enclosure for housing server racks. The example system includes a cooling ladder base, a cooling ladder wing, and a mixing chamber. A first conduit connects the air intake with the cooling ladder wing. A second conduit connects the cooling ladder wing with the cooling ladder base. An intake tunnel connects the cooling ladder base to the mixing chamber.

This structure of underground cooling ladders carry the ambient air downward into the earth through cooling ladder rungs in the cooling ladder wing such that the ambient air becomes geothermally cooled air. The geothermally cooled air is provided through the at least one intake tunnel to the mixing chamber for release into the container enclosure for the data center. A chimney vents hot air exhaust outside of the data center.

During operation, warm surface level air is taken in through the top of the cooling ladder air intake. From there air moves laterally through conduits or pipes to the cooling ladder wing or exterior exchanger boxes. Here, the air drops further below ground before returning to the cooling ladder base. This structure can be repeated any number of times to create various size geothermal ladders. The number of layers is determined as a design choice based on application (e.g., data center size, heat generated, etc.) and site parameters (e.g., water table, freeze depth, etc.).

The bottom rung of the geothermal ladder may include one or more upflow intake tunnels oriented substantially perpendicular to the geothermal ladder. The upflow intake tunnels may also incorporate booster fans to pump air to a mixing chamber. The mixing chamber may be located directly beneath the container cooling system. Air from multiple geothermal ladders may be mixed before being pumped up to the base of server racks through a series of pipes and booster fans.

Additional modular air filtration, humidifier, dehumidifier, and other such air handling cooling systems may be installed in the mixing chamber and connecting tube systems.

In an example, a number of computer or server racks may be arranged in a starburst pattern or “star” inside of the container. In the sealed hot center of the star layout, aerodynamic diverter plates and a conical vortex inducer to generate a vortex flow up and out through an exhaust chimney and fan cooling system on top of the container.

In an example, the system provides a high-density, high-powered containerized modular data center cooling system to support HPC, blockchain, decentralized applications, and other power intensive workloads. The system may be utilized in any of a wide variety of different types of applications, including edge networking, edge networking installations/facilities, 5G infrastructure purposes like fiber distribution points and other telecommunications. The modular containerized data center cooling system reduces or altogether eliminates the need for large air conditioning systems and/or extensive plumbing required for hydropic cooling used in existing modular data centers today. The system also provides a high power/rack ratio with significantly lower cooling costs. The star-shaped rack layout also reduces data center cabling costs.

Before continuing, it is noted that as used herein, the terms “includes” and “including” mean, but is not limited to, “includes” or “including” and “includes at least” or “including at least.” The term “based on” means “based on” and “based at least in part on.”

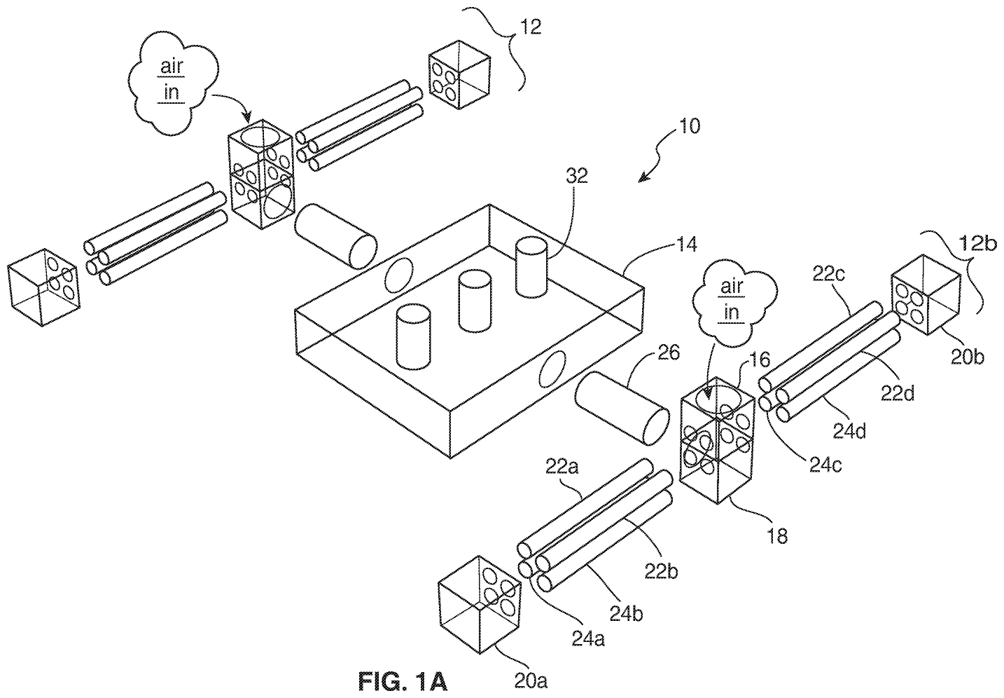

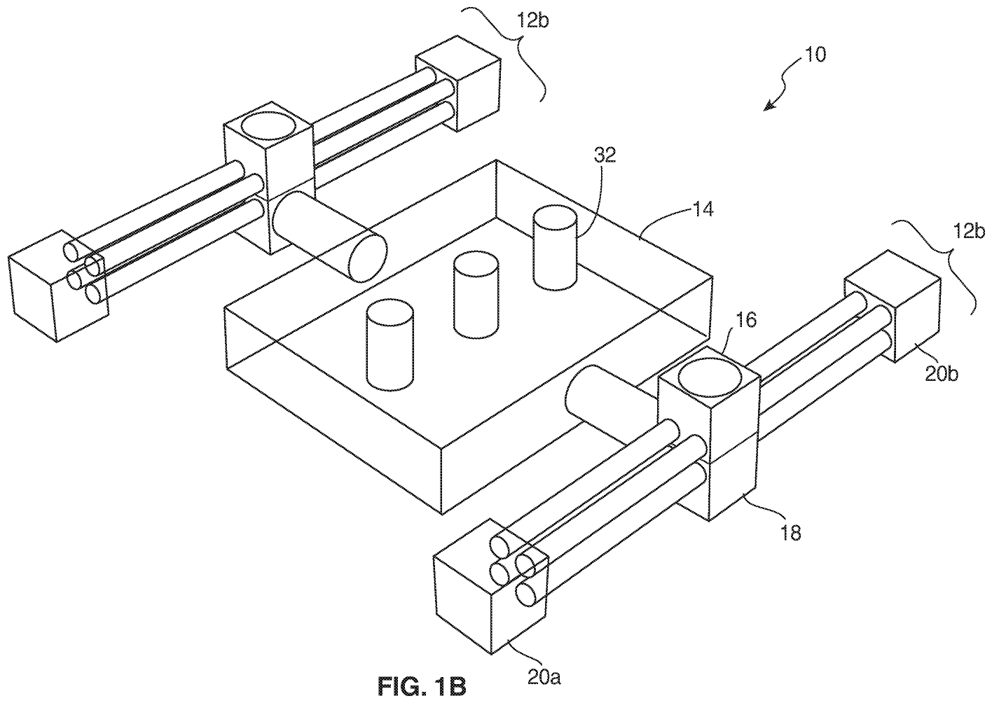

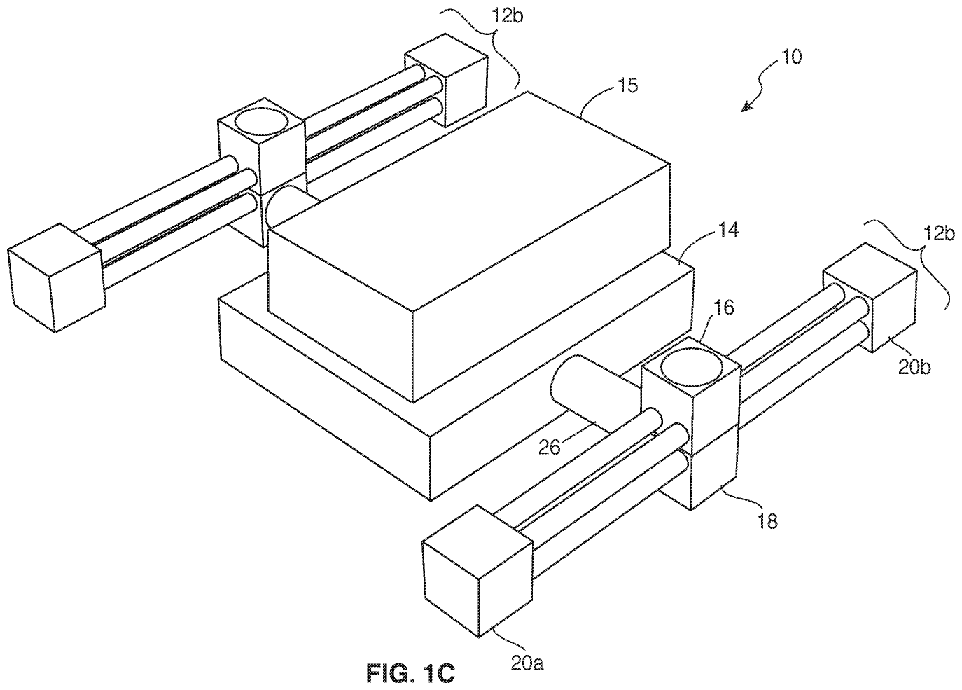

FIG. 1A is an exploded view of an example modular containerized data center cooling system. FIG. 1B is a perspective view of the example modular containerized data center cooling system of FIG. 1A. FIG. 1C is a perspective view of the example modular containerized data center cooling system.

The example system 10 for cooling a data center is illustrated having two cooling subsystems 12a and 12b, one on each side of a mixing chamber 14 below a containerized data center 15. It is noted however, that the example modular containerized data center cooling system 10 is an illustration of an example configuration. Given the modular nature of the cooling system 10, it will be readily apparent to those having ordinary skill in the art after becoming familiar with the teachings herein, that many other configurations may also be provided.

Each cooling subsystem 12a and 12b of the example system 10 includes an air intake 16 for drawing in ambient air from the surroundings (e.g., an outdoor environment). Air at ambient outdoor temperature may be drawn or forced into the system (e.g., using large fans). In an example, the air intake boxes sit at or just above ground level. The air intake boxes may be made from precast concrete or precast concrete sections.

A cooling ladder base 18 is positioned below the air intake 16. However, it is noted that the cooling ladder base 14 may be positioned in any suitable location and need not be positioned below the air intake 12.

In an example the cooling ladder base boxes are made of precast concrete or precast concrete sections, although other modes of manufacture are also contemplated. The cooling ladder base boxes are positioned just below ground level, such that their tops are at approximately the same level as the ground. In an example, additional cooling ladder base boxes may be stacked beneath the base boxes shown in the figure, as part of additional buried levels in the cooling ladder.

The example system 10 also includes a cooling ladder wing 20a and 20b on each side of the air intake 16. It is noted that any number of cooling ladder wings may be provided (one or more than two). The cooling ladder wings may be provided in any orientation relative to the air intake 16.

In an example, the cooling ladder wing boxes 20a are made from precast concrete or precast concrete sections, although again, any suitable manufacture material may be provided. The wing boxes sit at substantially the same underground level as their corresponding cooling ladder base boxes.

In an example, the air intake 16, the cooling ladder base 18, and the cooling ladder wings 20a, 20b may be containerized or containers. Containers enable various configurations of the system 10.

One or more conduit 22a-b and 22c-d connects upper outlet(s) of the air intake 16 with upper inlet(s) of each of the cooling ladder wings 20a, 20b, respectively.

One or more conduit 24a-b and 24c-d connects lower outlet(s) of the cooling ladder wings 20a, 20b, respectively, with inlet(s) on the side(s) of the cooling ladder base 18.

An intake tunnel 26 connects the cooling ladder base 18 to the mixing chamber 14.

In an example, all underground components (e.g., air intake 16, cooling base 18, cooling ladder wings 20a, 20b, along with the conduits) are made from precast concrete or precast concrete sections. The conduits may provide an underground tunnel system, e.g., for cables.

The structure defined by the underground components (e.g., the air intake 16, cooling base 18, cooling ladder wings 20a, 20b, along with the conduits), forms a system of underground cooling ladders 40 when installed at least partially underground.

Additional access to the mixing chamber 14 and connected tunnels may be provided through an access shaft. If the site permits it, maintenance tunnels connecting multiple cooling systems may be installed from precast concrete sections.

Air from the geothermal ladder systems is mixed in the mixing chamber 14 in order to provide a uniform temperature of the cooling airflow. In an example, the mixing chamber 14 is a buried rectangular box made from precast concrete or precast concrete sections, and takes in geothermally cooled air from two separate cooling ladder structures.

In an example, the mixing chamber 14 is between 1.5 times and 2.0 times the volume of the data container located directly above. The mixing chamber 14 may also house electrical and networking infrastructure that is brought up directly under data center equipment, and can be connected via tunnels to other modular containerized data center cooling systems.

In an example, the data center is provided as a container enclosure 15 that is positioned above the mixing chamber 14. The container enclosure 15 holds a flow space 28 and a floor 30 of the data center. At least one intake tunnel 32 carries the geothermally cooled air upward from the mixing chamber 14 to the flow space 28 beneath the floor 30 of the data center.

In an example, the upflow intake tunnels 32 are about 3-6 feet in diameter, and their length is determined by site parameters. Air is pulled out of the cooling ladder system and pushed into the upflow intake tunnels 32 by large fans located inside the upflow intake tunnels 32. In an example, the upflow intake tunnels 32 are buried cylindrical pipes made of precast concrete or precast concrete sections.

In an example, air flows upward through pipes 32. Fans within the air intakes 32 force geothermally cooled air up from the mixing chamber 14 and divert it to concentrate flow points (e.g., the support grid 29) in the flow space 28 around data center equipment 34.

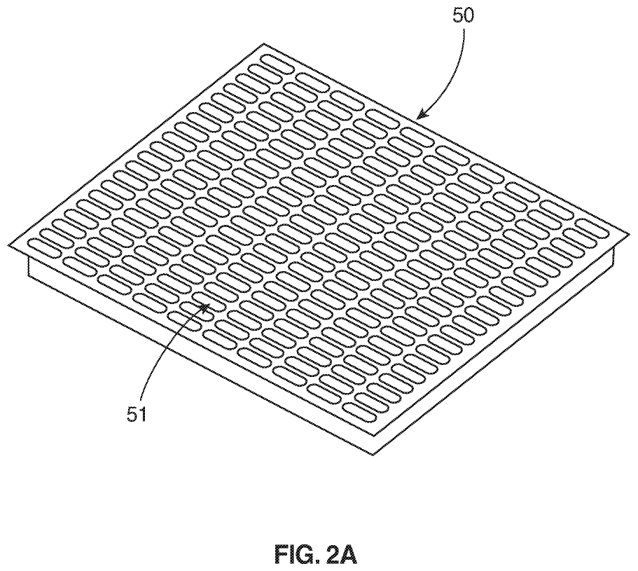

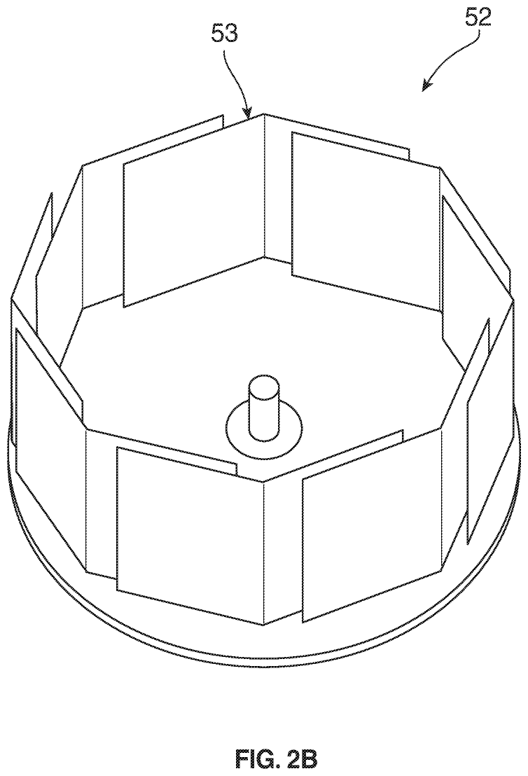

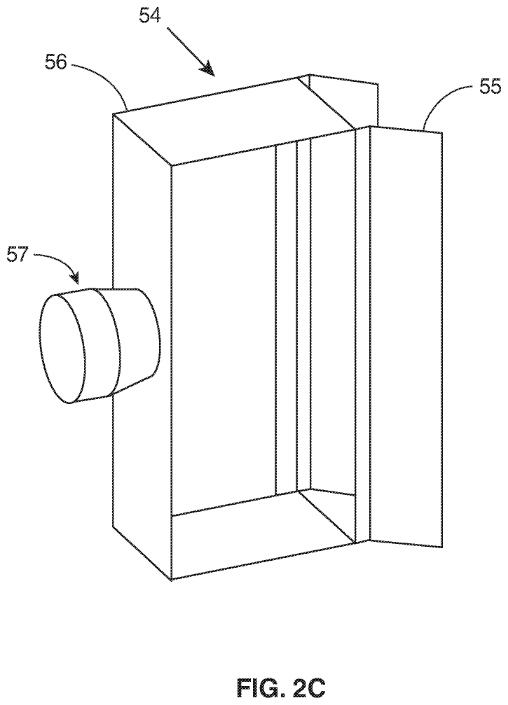

FIG. 2A is an example floor panel 50 for the modular containerized data center cooling system 10, specially configured with openings 51 to permit the passage of air through a subfloor into the main server chamber 15. In addition to providing structural support and a hollow space for geothermally cooled air to flow, the support and structure of raised floor 30 includes diverter plates and fans to redirect air to desired locations and in precise patterns in the data center.

Floor panels 50 provide a structural surface, or floor 30, upon which data center equipment can rest, and people can walk. The floor panels 50 may be positioned around key data center equipment may provide holes or openings 51 to allow the geothermally cooled air to flow upwards. In addition, some floor panels 50 may incorporate fans to ensure that upward-flowing air is able to reach equipment placed high above the floor. Other panels may be solid and/or only have partial openings, to create the desired airflow at various locations on the floor.

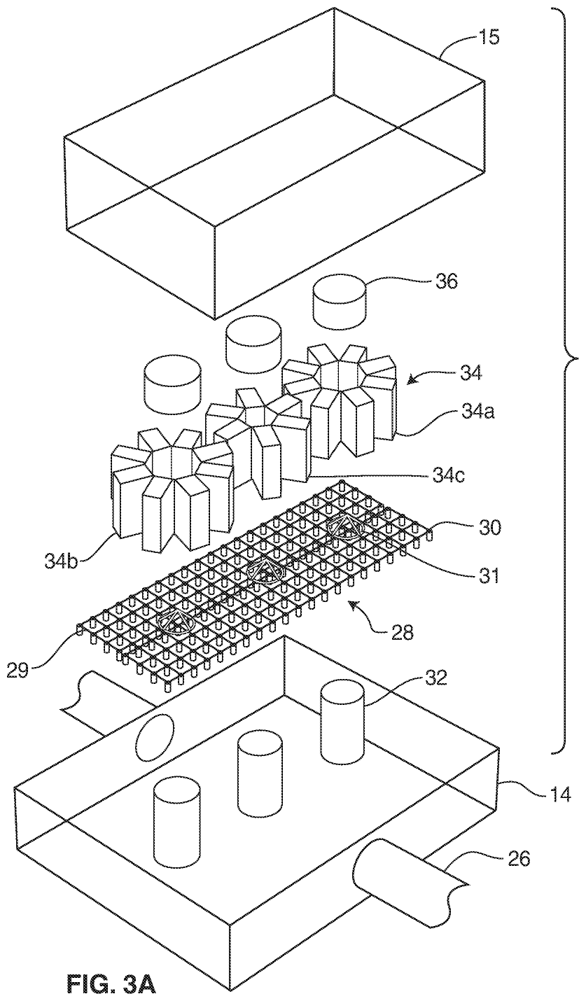

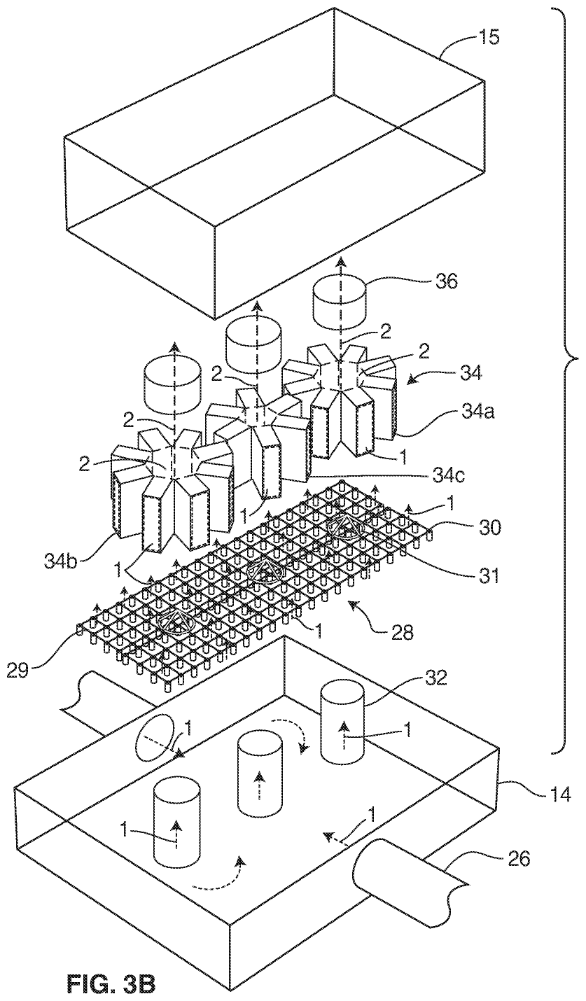

FIG. 2B is an example of a diverter 52 having a plurality of diverter plates 53 which may be installed inside of the server rack of the modular containerized data center cooling system 10, e.g., in addition to or in place of vortex-inducing exhaust diverters 31 (see, e.g., FIG. 3B).

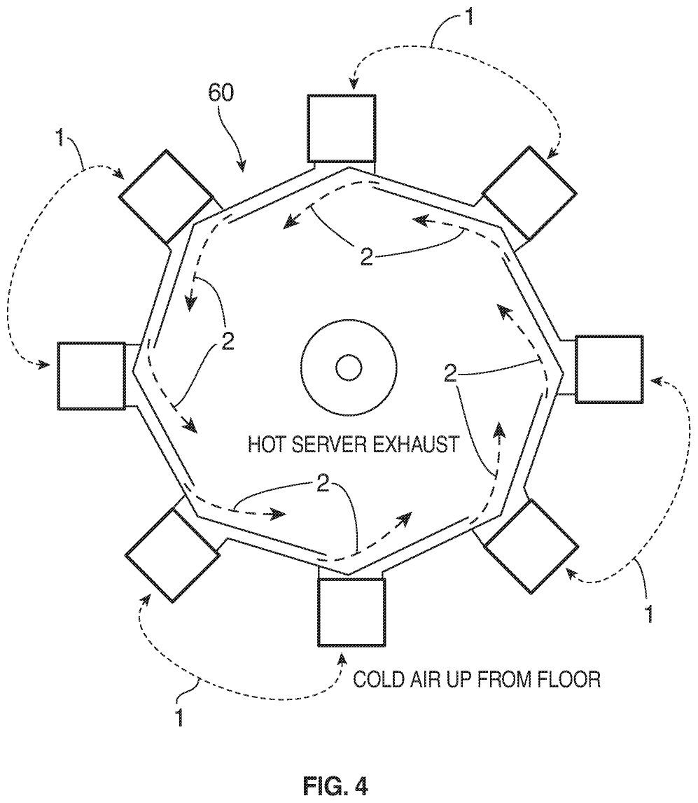

FIG. 2C is an example server box 54 for a server rack of the modular containerized data center cooling system 10. In an example, the server box 54 has a housing 56 with front facing intake 57 and rear facing exhaust. Diverter plates 55 may be provided to direct the exhaust and create the circular flow pattern, e.g., as illustrated in FIG. 4. A plurality of server boxes may be provided to form a “star-shaped” server rack.

FIG. 3A is an exploded view of the modular containerized data center cooling system 10 with a raised floor support and server rack star structures and exhaust chimneys. FIG. 3B is an exploded view of the modular containerized data center cooling system illustrating an example airflow pattern. FIG. 4 is a diagram illustrating an example airflow pattern through a server rack of the modular containerized data center cooling system. In FIGS. 3B and 4, cold airflow is illustrated by dashed arrows 1, and hot airflow (or exhaust) is illustrated by dashed arrows 2).

The container enclosure 15 may house a plurality of server racks 34 for the data center. In an example, the server racks 34 have a star-shape configuration (e.g., when viewed top-down).

The number of servers in each star configuration can vary based on design considerations, such as but not limited to, container dimensions, to accommodate for access, airflow, among other site requirements. In the example shown in FIG. 3A, two 8-leg rack star configurations and one 6-leg rack star configuration (in the center) is configured to provide a total of 22 racks.

In the example shown in the figure, the server racks 34 are star-shaped rings, also referred to as stars, server rings, or server stars. The two outside server racks 34a-b each include eight server racks in an arrangement that resembles a starburst when seen from above, with a central gap through which wiring and airflow may be provided. Each server rack 34 holds a plurality of servers, which are the computers that perform the data processing functions of the data center, including but not limited to high-performance computing, decentralized computing, streaming video, search engines, and blockchain hashing calculations or mining calculations. In the example shown in the figure, a third star or server ring 34c in the middle has six server racks arranged in a starburst pattern, with a central gap for wiring and airflow.

Each star has the hot exhaust (e.g., directed by diverters 55 in FIG. 2C) on the inside of the server boxes 54 facing in towards the center of the ring, and cold air intake side 57 (FIG. 2C) facing the exterior of the star or ring shape server ring 34. Air is pumped up and diverted directly in front of each rack in the star through a raised floor system. An example modular containerized data center 15 may have between 2 and 12 star cooling systems depending on size and configuration, although more or less may also be provided.

The server racks 34 are positioned on top of the floor structure, in an example on a track and/or on a seismic system to counter seismic activity. As previously noted, the floor structure 30 of the container(s) 15 may include a track subsystem that allows the server racks 34 to move easily between operation and maintenance positions. The track subsystem may be configured for easy access to both sides of the rack servers 34 when it is located in the maintenance position. Seismic stabilization may also be added to the floor system structure, or to the floor 30 panels beneath the rack servers 34.

In an example, airflow up through holes or openings in the floor panels 50 on the support grid 29, particularly those located in front of the server racks 34a-c, allows geothermally cooled air to flow upward through the front of the server racks 34a-c, in order to offset the heat generated by the server computers as they operate.

In an example, the design and configuration of each server rack 34a-c is such that electrical power devoted to computing is at least 75 kW per rack, while the design and configuration of the overall system is such that overall cooling power required per rack is substantially lower than with existing data centers.

Openings or holes in the floor 30 of the data center (e.g., floor panel 50 in FIG. 2A) may be provided to direct the geothermally cooled air predominantly against the front face(s) of the server racks 34. The back(s) or central cylindrical area inside of the server racks 34 may vent hot air exhaust (e.g., via diverter plates 55) toward a central opening on the rear of the server racks 34, from which the hot air exhaust is directed through one or more chimney 36.

A lower portion of the chimney 36 may be positioned inside the container enclosure 15 of the data center to receive the hot air exhaust from the server racks 34. An upper portion of the chimney 36 extends outside of the container enclosure 15 (e.g., through the top of the container enclosure 15) to vent the hot air exhaust outside of the data center.

In an example, the exhaust chimneys 36 are cylindrical chambers or conduits that are sealed along the sides but are open at the top and bottom. The chimney 36 may include vortex-inducing exhaust diverters 31 such as but not limited to conical-shaped diverter plates and/or aerodynamic diverter panels to force a vortex of hot air from data center equipment 34 upward so that it can be expelled from the modular containerized data center 15.

At their lower ends, the exhaust chimneys receive the upward-moving hot air from the vortex-inducing exhaust diverters 31. At their upper ends, the exhaust chimneys 36 expel the hot air into the ambient outdoor environment. This removes the heat generated by the servers from the interior of the modular containerized data center 15, allowing the temperature of the servers on racks 34 to remain substantially constant.

The floor panels 50 may also incorporate or support a track system such that data center equipment can be easily repositioned for easier access and maintenance, and to provide seismic bases at sites requiring them. The track system includes at least one rail for each bank of servers such that the individual server boxes of the server rack can expand outward, providing access to the center of the server rack. The track system allows each server rack 34 to be moved easily between operation and maintenance positions, allowing for easy access to all vertical faces of the rack when it is located in the maintenance position.

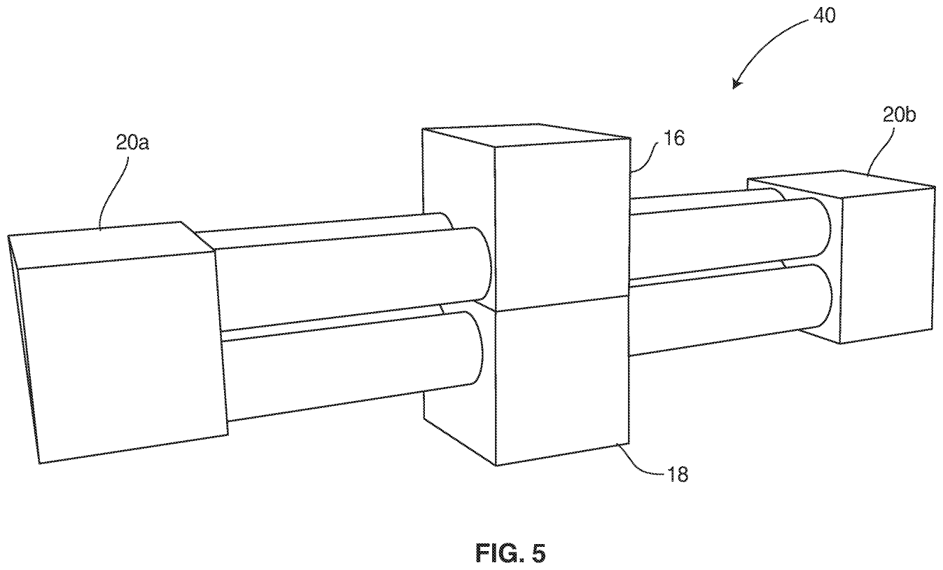

FIG. 5 is a perspective view of an example cooling ladder 40 of the example modular containerized data center cooling system 10. The cooling ladder(s) 40 are configured to carry the ambient air from the air intake 16, downward into the earth through cooling ladder “rungs” such that the ambient air becomes geothermally cooled air. The geothermally cooled air is provided through the intake tunnel 26 to the mixing chamber 14 for release into the data center.

The cooling ladder “rungs” are buried hollow pipes or conduits or other passages through which air is carried. In an example, the cooling ladder rungs are cylindrical pipes made from precast concrete or precast concrete sections. The bottom ‘rung’ of the geothermal ladder may provide a drain pit at the bottom which is equipped with pumping equipment if necessary for flood prone areas.

In an example, each air intake box and cooling ladder base box provides two apertures on one vertical face and two apertures on an opposite vertical face, and each cooling ladder wing box provides four apertures on a single vertical face, to which cooling ladder rungs may be attached, such that air may be passed between cooling ladder base boxes at different levels in the cooling ladder, and between the topmost cooling ladder base box and the air intake boxes.

During operation, the air moves laterally through the geothermal cooling ladder rungs, from the intake boxes to the wing boxes and then back to the cooling ladder base boxes. The air is cooled to ground temperature, with the depth and number of rungs in the cooling ladder determining how efficient this process is, and how deep the ground with which heat is exchanged. In an example, the depth of the geothermal ladder is a design choice based on the specifics of a given construction site.

The conduits of the cooling ladder 40 may be any suitable size. In an example, the conduits range in size from about a 1.5 ft radius to about a 6 ft radius. The length of the conduits is determined based site parameters, e.g., to achieve the desired geothermal cooling effect.

The air intake 16, cooling ladder base 18, and cooling ladder wings 20a, 20b may be any suitable size. In an example, the air intake 16, cooling ladder base 18, and cooling ladder wings 20a, 20b are concrete boxes about 7 ft by 7 ft by 7 ft.

The overall depth of the cooling subsystems 12a and 12b can be any suitable depth. In an example, the depth is based on the number of boxes stacked together to form the cooling ladder structure. For example, in FIGS. 1-4, the cooling ladder wings 20a, 20b are at a depth of approximately 8 feet, and the intake box is partially buried, sitting about 3.5 feet above ground level.

Additional boxes can also be stacked in the ladder structure, with each adding about 7 additional feet to the overall depth, corresponding the the dimensions of the box.

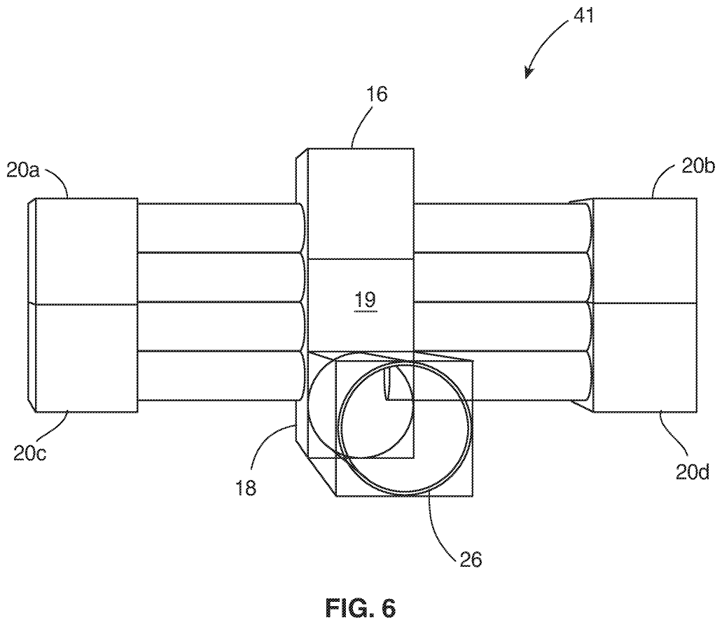

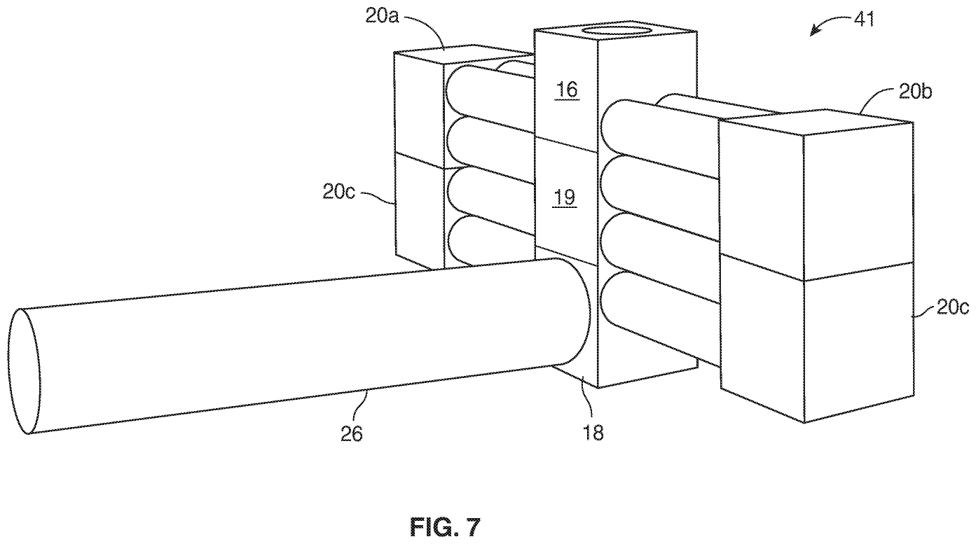

FIG. 6 is a front perspective view of another cooling ladder 41 of the example modular containerized data center cooling system 10. FIG. 7 is a side perspective view of the cooling ladder 41 in FIG. 6. In FIGS. 6 and 7, two cooling ladder wings 20a, 20c and 20b, 20d (with associated conduits) are shown for purposes of illustration. Also in the configuration of FIGS. 6 and 7, an additional cooling ladder base 19 is provided.

The tunnels and other buried portions of the cooling subsystem 12a, 12b may be accessible through one or more access shaft that goes down along the center of the exchanger boxes, with sealed access hatches to each level of the exchanger.

In configurations where multiple container cooling systems are placed near one another, cabling between cooling systems can be routed through the underground tunnel system.

Fire suppression and electrical infrastructure may also be placed in the tunnel system at the level of the mixing chamber 14.

The above ground intake port on the exchanger or air intake boxes, as well as the roof of the container 15, can also optionally be equipped with a solar array and battery system to power fans in the intake system or other infrastructure.

Before continuing, it should be noted that the examples described above are provided for purposes of illustration, and are not intended to be limiting. Other devices and/or device configurations may be utilized to carry out the operations described herein.

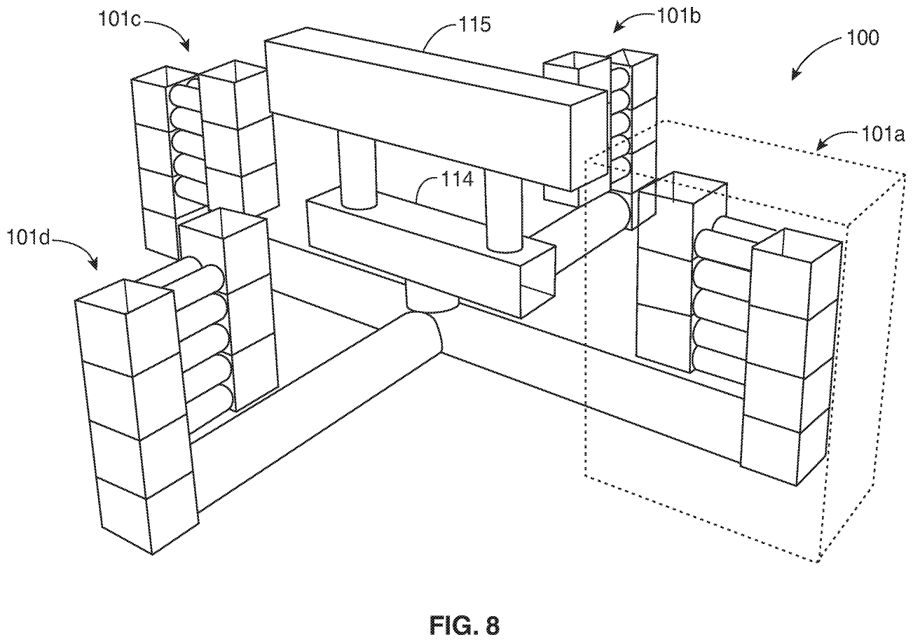

FIG. 8 is a perspective view of another modular containerized data center cooling system 100. In this example, the container enclosure 115 sits above mixing chamber 114 and provides structure, containment, and environmental protection to the server racks, the floor and cooling space beneath them, and the exhaust equipment located above them. In an example, the container enclosure 115 is insulated to minimize conduction of heat from the outdoor environment into the interior of the container, and covered in a light-colored or reflective surface to minimize absorption of solar radiation by the container enclosure.

In the example shown in the Figure, the container enclosure 15 consists of one or more “high cube” shipping containers 40 feet in length and 9.5 feet in width and height. In another example, the container enclosure includes several standard 20′ or 40′ shipping containers specially modified to fit together to form a single larger container that allows for sufficient work space around the star racks.

The cooling ladder of an example modular containerized data center cooling system 100 includes four cooling ladders 101a-d, including wing boxes, two cooling ladder base boxes, one air intake box, one upflow intake tunnel, and sixteen cooling ladder rungs (eight visible and eight hidden by this view), with a human added for scale.

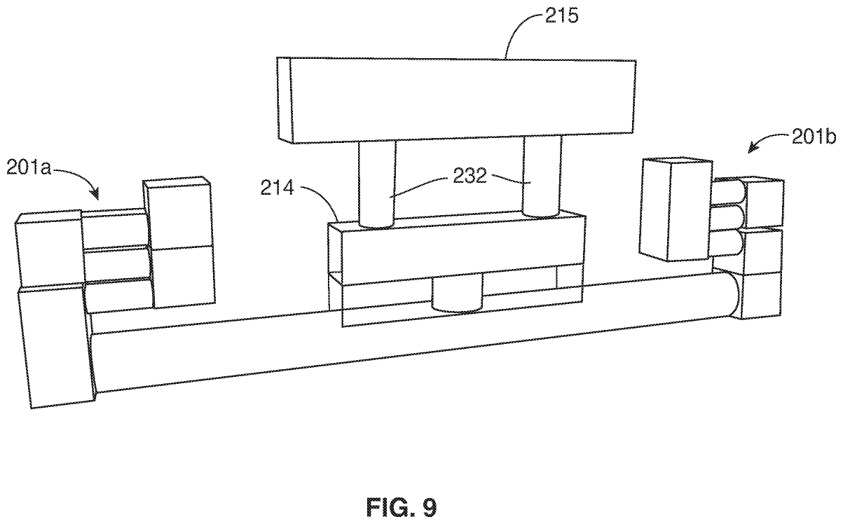

FIG. 9 is a perspective view of another modular containerized data center cooling system 200. In this example, the data center 215 is raised above the upflow air intake tunnels 232 and the mixing chamber 214, which are at least partially buried at a deeper level than the cooling ladders 201a, 201b. This and other arrangements may be selected as a design choice based on desired performance and the specifics of a given construction site.

The configurations and operations shown and described herein are provided to illustrate example implementations. It is noted that the configurations and operations are not intended to be limiting. Still other configurations and operations may also be implemented, as will be readily apparent to those having ordinary skill in the art after becoming familiar with the teachings herein.

Other example configurations and operations that may be incorporated into the datacenter cooling system 10 may include, but are not limited to, air filtering, humidifiers, and other environmental control cooling systems that can be fitted in the up flow intake tunnels, mixing chamber, and ring intake and diverter segments.

It is also possible to incorporate the newer style of polarized media filter to act as both a heat sink and heat exchanger at the same time. Humidifiers may be employed in dry environments to reduce air temperature (as with a swamp cooler), to increase humidity, and to reduce the risk of static discharge. Modular environmental control cooling systems can be fitted into the system to incorporate dehumidifiers for wet climates where condensation may be an issue, or the previously mentioned humidifiers and/or air filter systems.

A thermal/heat capture cooling system may be provided that fits into the exhaust chimney and acts like a traditional heat exchanger. The warm fluid running through the system could be used in things like radiant in-floor heating, or to supply heated concrete and roads throughout residential, commercial and industrial real-estate developments, to heat greenhouses in climates where year round outdoor farming is not viable, to heat outdoor sports fields (much like a hockey rink in reverse), wherein the ground under the grass is kept warm enough for fields to be maintained in the winter.

The system may also incorporate solar panels, wind turbines, or micro hydroelectric generators, combined with battery arrays on and around the cooling systems, or with batteries buried nearby, or stored inside subterranean components of the modular containerized data center cooling system, or located in any other convenient location as a design choice. These elements could be used to provide backup or to power the air movement systems (fans), interior lights, etc. of the modular containerized data center cooling system.

It is noted that the examples shown and described are provided for purposes of illustration and are not intended to be limiting. Still other examples are also contemplated.

1. A system for cooling a data center, comprising:
an air intake for ambient air from an outdoor environment;
a cooling ladder base positioned below the air intake;
a cooling ladder wing;
a mixing chamber;
a first conduit connecting an upper outlet of the air intake with an upper inlet of the cooling ladder wing;
a second conduit connecting a lower outlet of the cooling ladder wing with an inlet of the cooling ladder base; and
an intake tunnel connecting the cooling ladder base to the mixing chamber;
wherein underground cooling ladders carry the ambient air downward into the earth through cooling ladder rungs in the at least one cooling ladder wing such that the ambient air becomes geothermally cooled air, and the geothermally cooled air is provided through the at least one intake tunnel to the mixing chamber for release into the data center.

2. The system of claim 1, further comprising a container enclosure for the data center.

3. The system of claim 2, wherein the container enclosure holds a flow space and a floor of the data center.

4. The system of claim 3, further comprising at least one ring intake to carry the geothermally cooled air upward from the mixing chamber to the flow space beneath the floor of the data center.

5. The system of claim 2, wherein the container enclosure holds a plurality of server racks for the data center.

6. The system of claim 5, wherein the server racks have a star-shape configuration when viewed top-down.

7. The system of claim 6, further comprising holes in a floor of the data center to direct the geothermally cooled air predominantly against front faces of the server racks.

8. The system of claim 7, wherein a back of the server racks vent hot air exhaust toward at least one central opening from which the hot air exhaust is directed through at least one chimney.

9. The system of claim 2, further comprising a chimney, a lower portion of the chimney provided inside the container enclosure of the data center, and an upper portion of the chimney vents outside the container enclosure to vent hot air exhaust outside of the data center.

10. The system of claim 1, wherein the air intake, the cooling ladder base, the cooling ladder wing, and the mixing chamber are containerized.

11. The system of claim 10, further comprising a containerized data center.

12. The system of claim 11, further comprising rails located on a floor of the data center beneath server racks in the data center, such that the server racks are easily moved from an operating position wherein only a front of the server racks are accessible, to a maintenance position wherein all sides of the server racks are accessible.

13. A system for cooling a data center, comprising:
a container enclosure for the data center;
at least one air intake to collect surface level ambient air from an outdoor environment;
at least one one cooling ladder base positioned below the at least one air intake;
at least one cooling ladder wing;
a mixing chamber under the container enclosure for the data center;
at least one first conduit connecting an upper outlet of the at least one air intake with an upper inlet of the at least one cooling ladder wing;
at least one second conduit connecting a lower outlet of the at least one cooling ladder wing with an inlet of the at least one cooling ladder base; and
at least one intake tunnel connecting the cooling ladder base to the mixing chamber;
wherein underground cooling ladders carry the ambient air downward into the earth through cooling ladder rungs in the at least one cooling ladder wing such that the ambient air becomes geothermally cooled air, and the geothermally cooled air is provided through the at least one intake tunnel to the mixing chamber for release into the container enclosure for the data center.

14. The system of claim 13, further comprising at least one ring intake to carry the geothermally cooled air upward from the mixing chamber to a flow space beneath a floor of the container enclosure for the data center.

15. The system of claim 13, wherein the container enclosure holds a plurality of server racks for the data center, the server racks having a star-shape configuration.

16. The system of claim 15, further comprising holes in a floor of the data center to direct the geothermally cooled air predominantly against a front face of the server racks, and a back of the server racks vent hot air exhaust toward one or more central openings from which the hot air exhaust is directed through at least one chimney.

17. The system of claim 13, further comprising at least one chimney, a lower portion of the at least one chimney provided inside the container enclosure of the data center, and an upper portion of the at least one chimney vents outside the container enclosure to vent hot air exhaust outside of the data center.

18. A system for cooling a data center, comprising:
a container enclosure for the data center, the container enclosure housing a plurality of server racks for the data center, the server racks having a star-shape configuration;
at least one air intake to collect surface level ambient air from an outdoor environment;
at least one one cooling ladder base positioned below the at least one air intake;
at least one cooling ladder wing;
a mixing chamber under the container enclosure for the data center;
at least one first conduit connecting an upper outlet of the at least one air intake with an upper inlet of the at least one cooling ladder wing;
at least one second conduit connecting a lower outlet of the at least one cooling ladder wing with an inlet of the at least one cooling ladder base;
at least one intake tunnel connecting the cooling ladder base to the mixing chamber;
at least one ring intake to carry the geothermally cooled air upward from the mixing chamber to a flow space beneath a floor of the container enclosure for the data center, wherein underground cooling ladders carry the ambient air downward into the earth through cooling ladder rungs in the at least one cooling ladder wing such that the ambient air becomes geothermally cooled air, and the geothermally cooled air is provided through the at least one intake tunnel to the mixing chamber for release into the container enclosure for the data center; and
at least one chimney to vent hot air exhaust outside of the data center.

19. The system of claim 18, further comprising holes in a floor of the data center to direct the geothermally cooled air predominantly against a front face of the server racks, and a back of the server racks vent hot air exhaust toward one or more central openings from which the hot air exhaust is directed through at least one chimney.

20. The system of claim 18, wherein the at least one air intake, the at least one one cooling ladder base, the at least one cooling ladder wing, and the mixing chamber are containerized.
